(19) United States
(12) Patent Application Publication
(10) Pub. No.: US 2026/0082997 A1
(43) Pub. Date: Mar. 19, 2026

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Chao-Wei Chiu, Hsinchu City (TW); Hsuan-Ting Kuo, Taichung City (TW); Hao-Jan Pei, Hsinchu (TW); Hsiu-Jen Lin, Hsinchu County (TW); Ching-Hua Hsieh, Hsinchu (TW)

(73) Assignee: Taiwan Semiconductor Manufacturing Company, Ltd., Hsinchu (TW)

(21) Appl. No.: 18/889,329

(22) Filed: Sep. 18, 2024

(51) Int. Cl. H01L 25/16; H01L 21/56; H01L 23/00; H01L 23/31; H01L 23/538; H01L 27/146

(52) U.S. Cl. CPC H10W 90/00; H10F 39/806; H10W 74/014; H10W 74/134; H10W 74/141; H10W 70/60; H10W 70/611; H10W 80/327

(57) ABSTRACT

A semiconductor package includes a first die and a second die disposed side-by-side, an encapsulant laterally covering the first die and the second die, and an interconnect structure underlying the encapsulant. Each of the first die and the second die includes a front side and a back side opposite to each other. The second die further includes an optical interface at the back side, and a top surface of the back side of the second die and the optical interface are exposed by the encapsulant. The interconnect structure is connected to the front sides of the first and second dies, and the second die is electrically coupled to the first die through the interconnect structure.

### BACKGROUND

The semiconductor industry has experienced rapid growth due to ongoing improvements in the integration density of a variety of semiconductor components (e.g., transistors, diodes, resistors, capacitors, etc.). For the most part, improvement in integration density has resulted from iterative reduction of minimum feature size, which allows more semiconductor components to be integrated into a given area. As the demand for shrinking semiconductor components has grown, a tendency for smaller and more creative packaging techniques of semiconductor dies has emerged. Although existing semiconductor package and manufacturing method thereof have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C are schematic cross-sectional views illustrating different types of integrated circuit (IC) dies, in accordance with some embodiments.

FIG. 1D is a schematic top view illustrating the IC die shown in FIG. 1C, in accordance with some embodiments.

FIGS. 2A-2B and FIGS. 2E-2I are schematic cross-sectional views illustrating a manufacturing method of a semiconductor package at various stages, in accordance with some embodiments.

FIGS. 2C-2D are schematic top views illustrating different configurations of the structure shown in FIG. 2B, in accordance with some embodiments.

FIG. 3 is a schematic cross-sectional view illustrating the semiconductor package of FIG. 2I coupled to an optical signal port, in accordance with some embodiments.

FIGS. 4A-4D are schematic cross-sectional views illustrating a manufacturing method of a semiconductor package at various stages, in accordance with some embodiments.

FIGS. 5-6 are schematic cross-sectional views illustrating a semiconductor package, in accordance with alternative embodiments.

FIG. 7 is a flowchart illustrating a method of forming a semiconductor package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Currently, a semiconductor die including both photonic integrated circuit (PIC) and electronic integrated circuit (EIC) is becoming increasingly popular for its compactness. In addition, due to the widely use of optical fiber-related applications for signal transmission, optical signaling and processing have been used in more applications. Embodiments of the present disclosure provide novel methods of forming semiconductor packages and structures thereof, wherein the semiconductor package includes an integrated circuit (IC) die including a PIC bonded to an EIC, and the IC die is laterally encapsulated by an insulating encapsulant without damaging the optical path of the IC die. A sacrificial film covers the optical path of the IC die during the formation of the insulating encapsulant, and then the sacrificial film may be removed after the formation of the insulating encapsulant to reveal the optical path of the IC die. Alternatively, the optical path of the IC die may be revealed by the insulating encapsulant using suitable removal process to prevent the optical path from damaging during the grinding process. In this manner, the IC die including the optical path is protected by the insulating encapsulant to provide better reliability, and damage to the optical path of the IC die due to the grinding process is eliminated. In addition, the IC die including the PIC and the EIC may be electrically coupled to one or more IC dies using a short electrical signal path, thereby improving signal performance and increasing the data transmission rate.

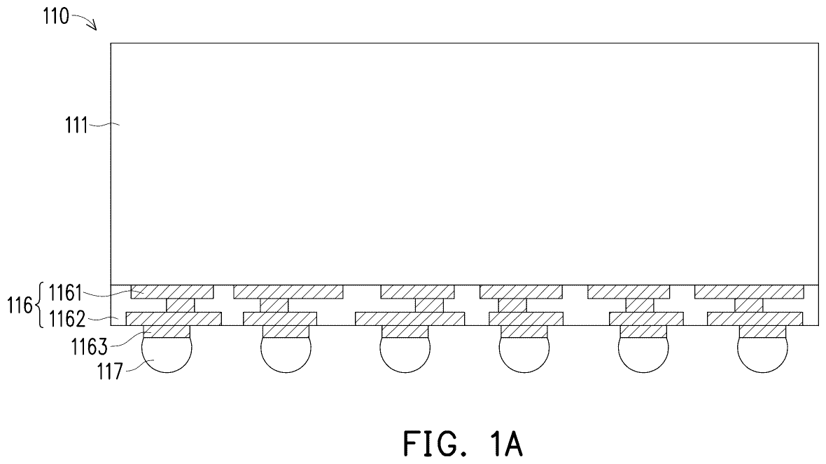

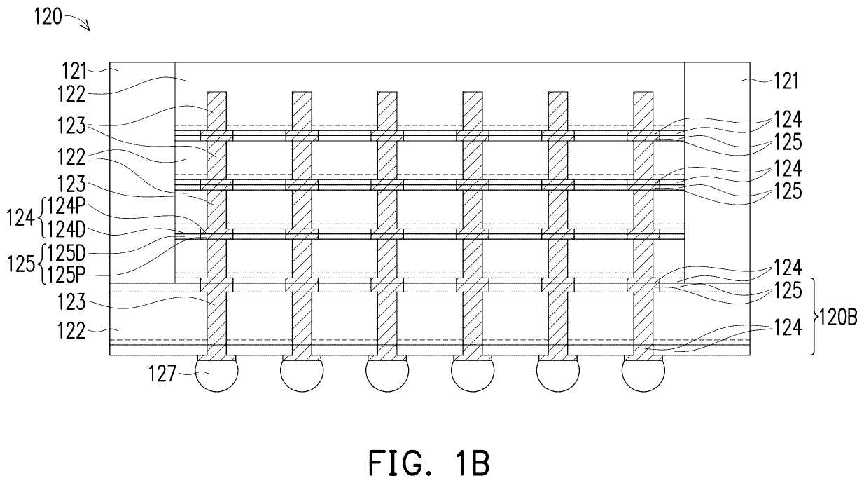

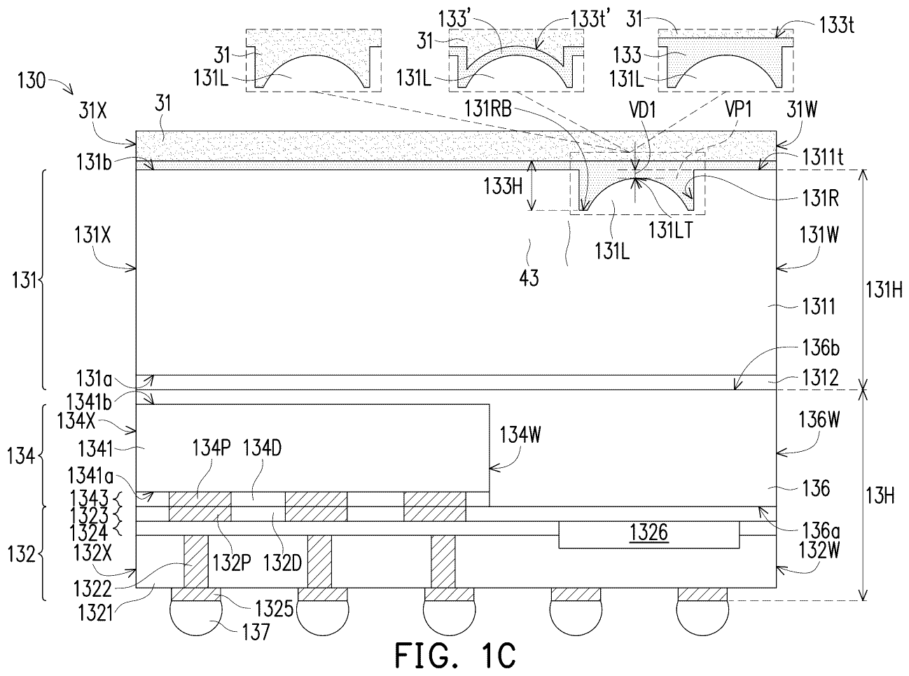

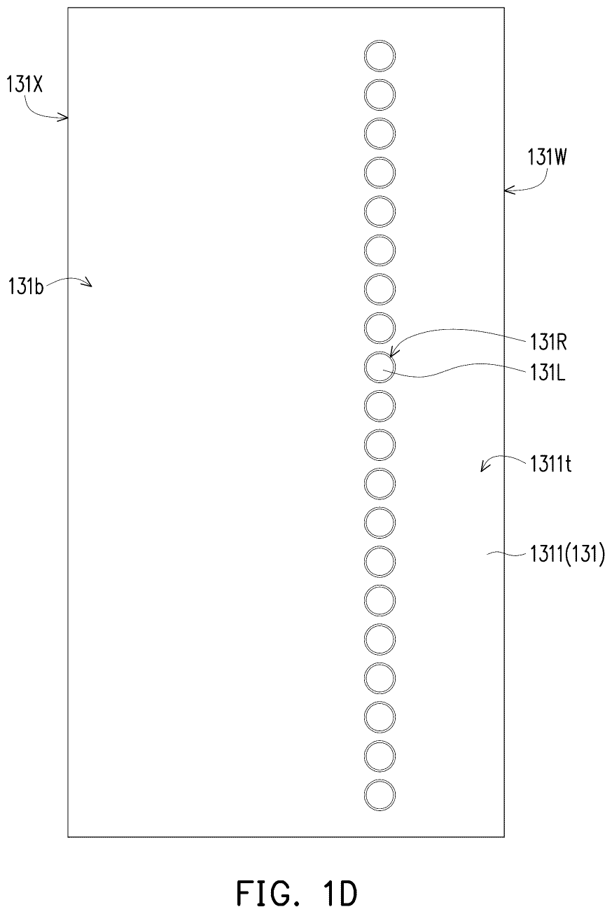

FIGS. 1A, 1B, and 1C are schematic cross-sectional views illustrating different types of IC dies, and FIG. 1D is a schematic top view illustrating the die shown in FIG. 1C, in accordance with some embodiments. Referring to FIG. 1A, an IC die 110 may be provided. The IC die 110 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

With continued reference to FIG. 1A, the IC die 110 may be formed in a semiconductor wafer, which may include different device regions that are singulated to form a plurality of IC dies 110. The IC die 110 may be processed according to applicable manufacturing processes to form integrated circuits. For example, the IC die 110 includes a semiconductor substrate 111, such as silicon, doped or undoped, or an active layer of a semiconductor-on-insulator (SOI) substrate. The semiconductor substrate 111 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The IC die 110 may include active devices (e.g., transistors, diodes, etc.), passive devices (e.g., capacitors, resistors, inductors, etc.), a combination thereof, etc. These active/passive devices (not individually shown) may be formed in/on the front side of the semiconductor substrate 111 using suitable front-end-of-line (FEOL) processes.

Still referring to FIG. 1A, the IC die 110 may include an interconnect structure 116 formed over the semiconductor substrate 111 and interconnecting the active and/or passive devices to form integrated circuits. For example, the interconnect structure 116 is formed by metallization patterns 1161 in one or more dielectric layer(s) 1162. The metallization patterns 1161 include metal pads, metal lines, and metal vias formed in the dielectric layer 1162 and electrically coupled to the active and/or passive devices. The interconnect structure 116 may include contact pads 1163 formed on the dielectric layer 1162 and electrically coupled to the metallization patterns 1161. The IC die 110 may include die connectors 117 formed on the contact pads 1163. The side of the IC die 110 where the die connectors 117 are distributed on may be viewed as an active side of the IC die 110. The die connectors 117 may be formed of a conductive material that is reflowable (e.g., solder), or may include other suitable conductive material(s) such as copper, aluminum, gold, nickel, silver, palladium, tin, the like, or a combination thereof. In some embodiments, the die connectors 117 are referred to as micro-bumps. The above examples are provided for illustrative purposes only, and other embodiments may utilize additional elements. In some embodiments, a chip probe (CP) testing is performed on the IC die 110 to ascertain whether the IC die 110 is a known good die (KGD). Thus, only IC dies 110, which are KGDs, undergo subsequent processing and are packaged, while other dies, which fail the CP testing, are not packaged.

Referring to FIG. 1B, an IC die 120 may be provided. For example, the IC die 120 is a memory device such as a hybrid memory cube (HMC) module, a high bandwidth memory (HBM) module, or the like that includes multiple memory dies. In some embodiments, the IC die 120 includes multiple tiers stacked upon and bonded to one another. Each tier of the IC die 120 may include a semiconductor substrate 122, through-substrate vias (TSVs) 123 formed in the semiconductor substrate 122, and a bonding layer 124 formed over a side (e.g., a front side) of the semiconductor substrate 122, and optional bonding layer 125 formed over an opposing side (e.g., a backside) of the semiconductor substrates 122. The material of the semiconductor substrate 122 may be selected from the candidate substrate material of the semiconductor substrate 111. Each of the bonding layers (124 and 125) may include bonding pads (124P and 125P) laterally covered by a bonding dielectric layer (e.g., 124D and 125D). The bonding pads 124P of the upper tier may be bonded to the bonding pads 125P of the lower tier in a one-to-one correspondence. The bonding dielectric layer 124D of the upper tier may be fused to the bonding dielectric layer 125D of the lower tier.

With continued reference to FIG. 1B, the bottommost tier 120B of the IC die 120 may have a lateral dimension greater than a lateral dimension of any one of the tiers stacked over the bottommost tier 120B. In some embodiments, an encapsulant 121 is disposed on the bottommost tier 120B and laterally covers the tiers stacked over the bottommost tier 120B. The IC die 120 may include die connectors 127 formed below the bottommost tier 120B and electrically connected to the bonding layer 124. The side of the IC die 120 where the die connectors 127 are distributed on may be viewed as an active side of the IC die 120. The die connectors 127 may be formed of a conductive material that is reflowable, (e.g., solder), or may include one or more conductive material(s) such as copper, aluminum, gold, nickel, silver, palladium, tin, the like, or a combination thereof. The above examples are provided for illustrative purposes only, and other embodiments may utilize additional elements. A CP testing may be performed on the IC die 120 to ascertain whether the IC die 120 is a KGD. Thus, only IC dies 120, which are KGDs, undergo subsequent processing and are packaged, while other dies, which fail the CP testing, are not packaged.

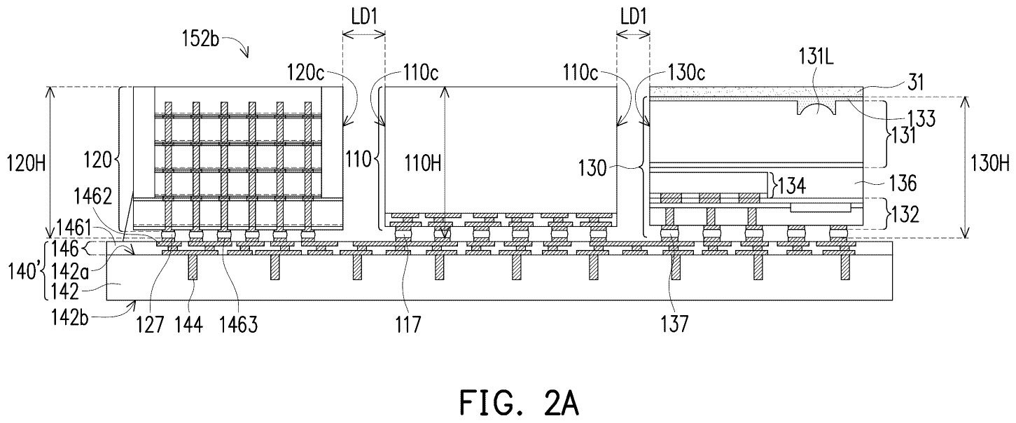

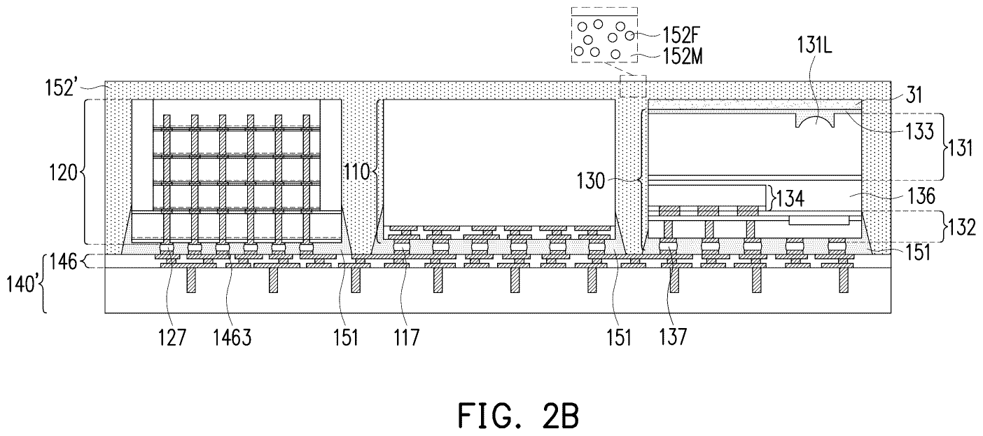

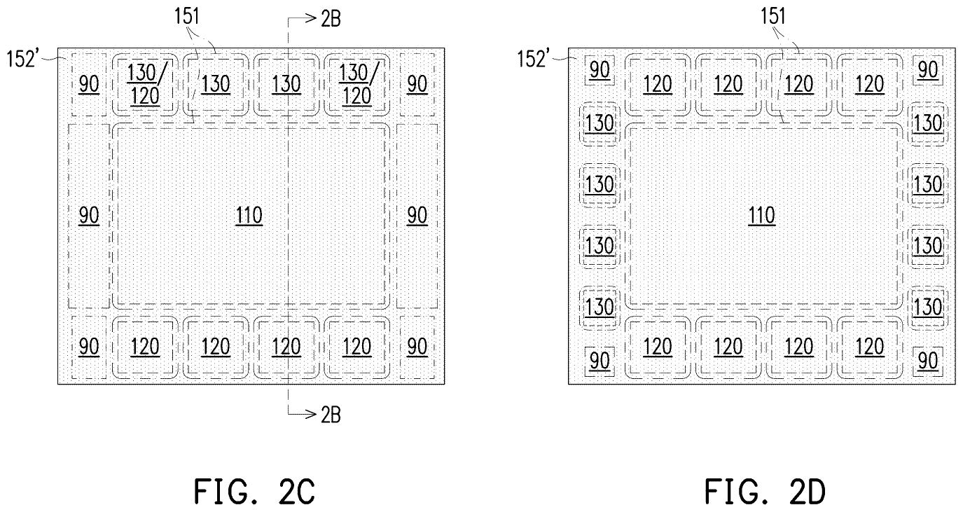

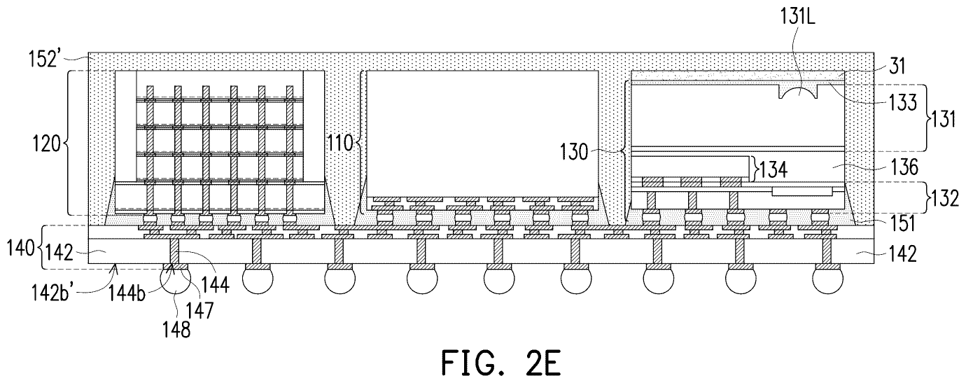

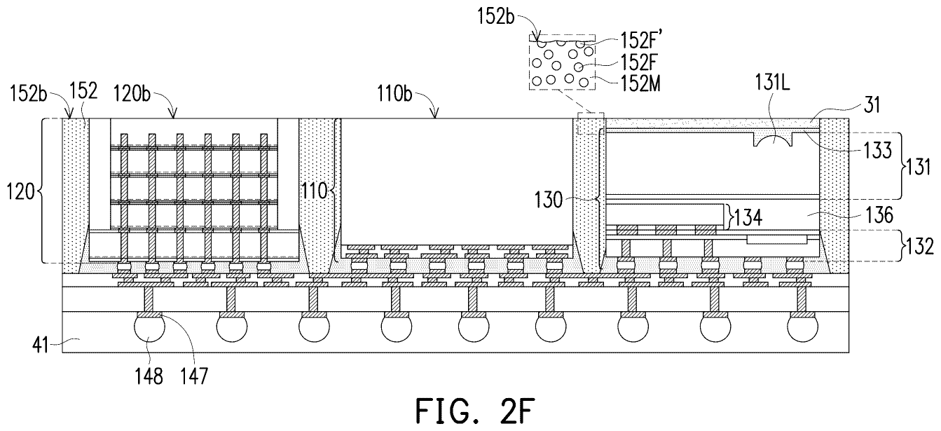

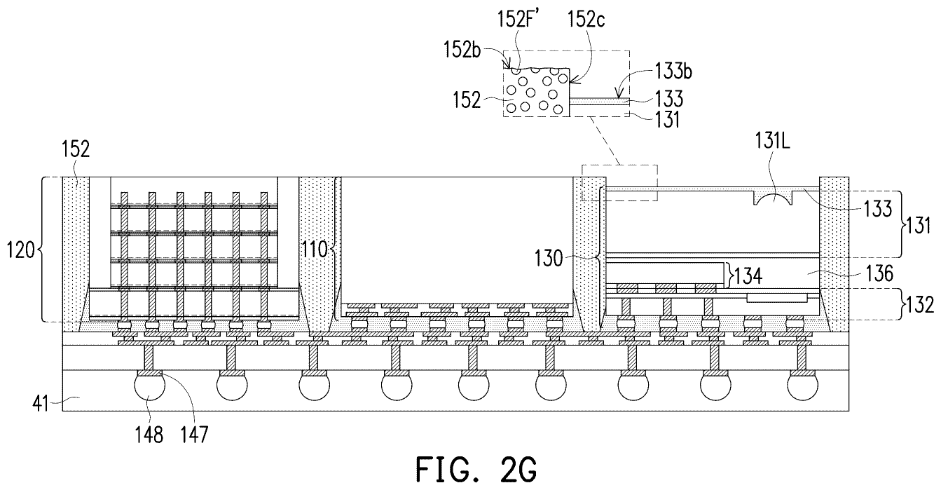

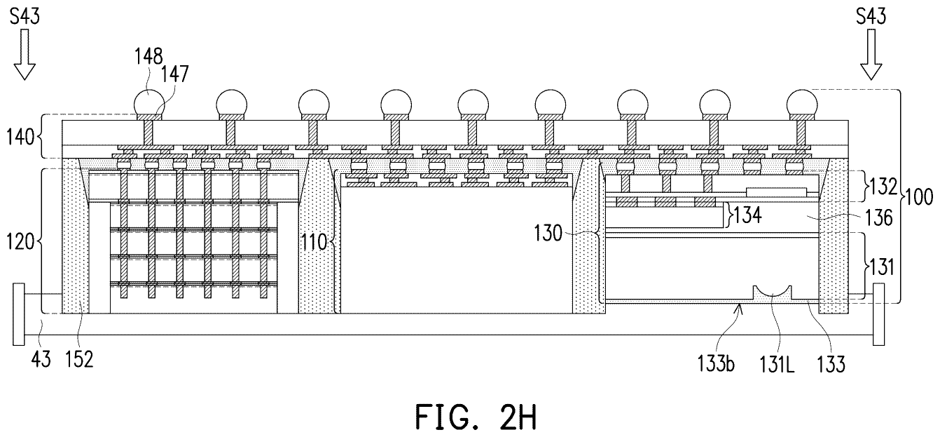

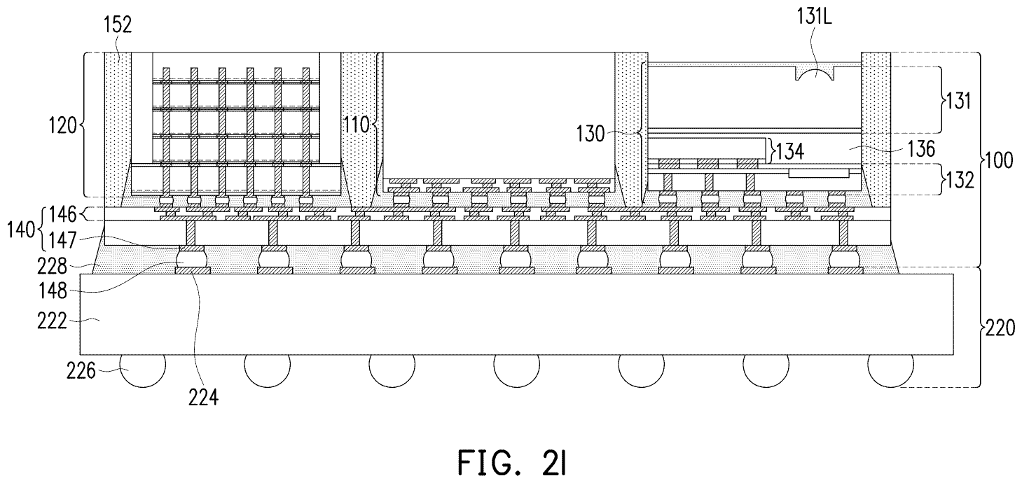

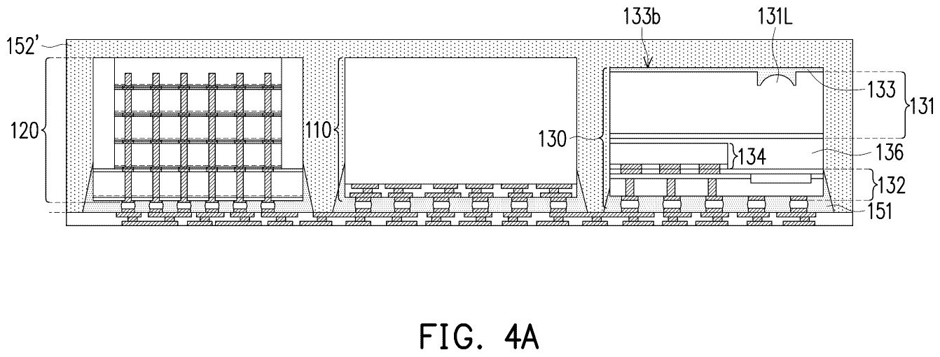

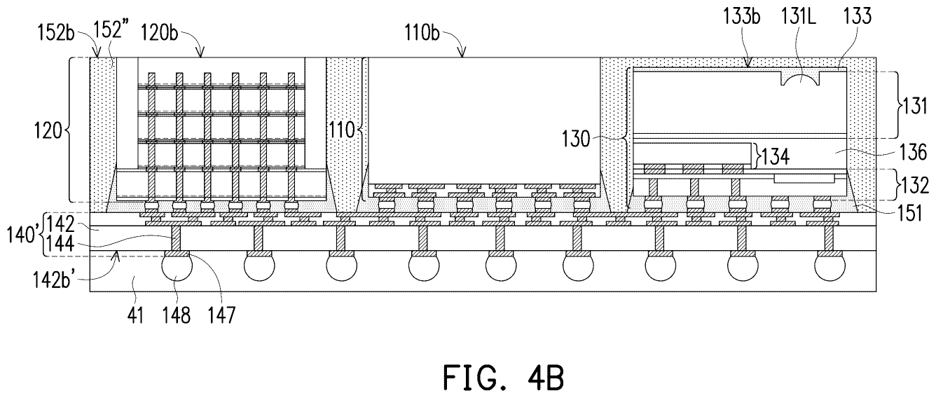

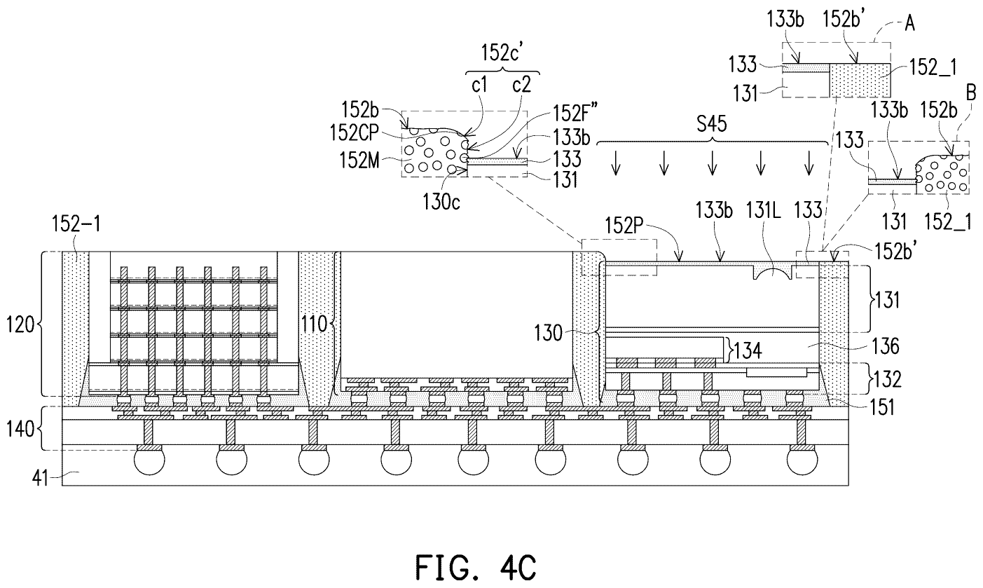

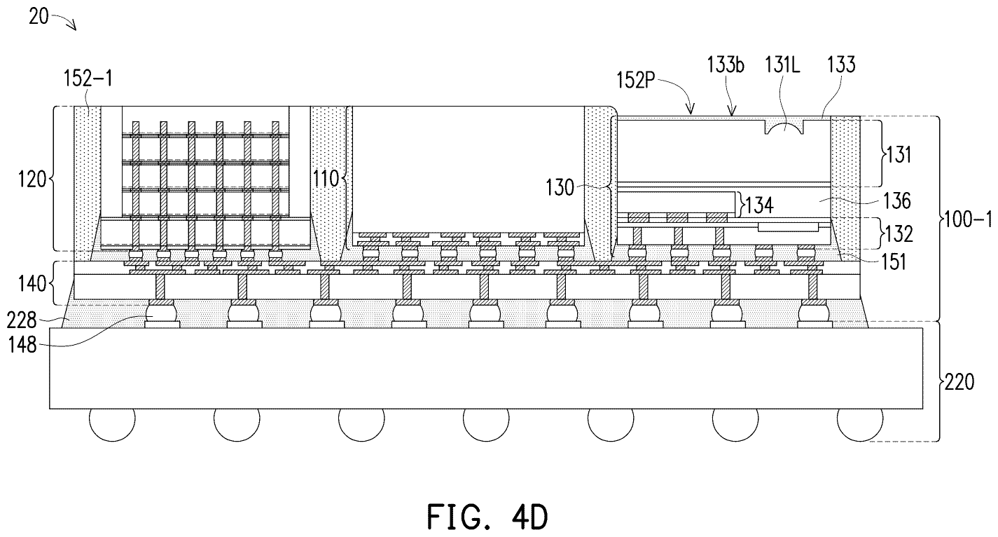

Referring to FIG. 1C, an IC die 130 may be provided with a sacrificial film 31. In alternative embodiments, the IC die 130 is not provided with the sacrificial film 31 (see FIG. 4A). The sacrificial film 31 may be considered sacrificial in the sense that it will be ultimately removed, according to some embodiments. The material of the sacrificial film 31 may include any suitable polymeric material which may be removed by, for example, dissolving the sacrificial film 31 in suitable solvent, etching the sacrificial film 31 using appropriate chemical solution, etc. The details of the removal process may be described in accompanying with FIG. 2F.

In some embodiments, the IC die 130 is an optical-engine (OE) die including an EIC 134 stacked upon and bonded to a PIC 132. In some embodiments, the EIC 134 exchanges electrical signals with the PIC 132. The PIC 132 may convert electrical signals from the EIC 134 to optical signals. For example, the PIC 132 includes a substrate 1321, through substrate vias (TSVs) 1322 penetrating through the substrate 1321, a bonding layer 1323 disposed over the substrate 1321, an optional routing layer 1324 interposed between the substrate 1321 and the bonding layer 1323 to electrically couple the bonding layer 1323 to the TSVs 1322, and contact pads 1325 formed below the substrate 1321 and electrically coupled to the TSVs 1322. The PIC 132 may include one or more optical component(s) 1326 to process, receive, and/or transmit optical signals, where the optical component 1321 may include photodiodes or photo-sensors, couplers, waveguides, laser sources, modulators, the like, a combination thereof, etc. The optical component 1321 may be formed in/on the substrate 1321 and may be partially or fully covered by the routing layer 1324 and/or the bonding layer 1323.

With continued reference to FIG. 1C, the EIC 134 may include a substrate 1341 including a front side 1341a and a backside 1341b opposite to the front side 1341a, and a bonding layer 1343 disposed over the front side 1341a of the substrate 1341 and physically and electrically bonded to the bonding layer 1323 of the PIC 132. The EIC 134 may include active devices and/or passive devices (not individually shown) formed in/on the substrate 1341 to form functional circuits for processing the electrical signals converted from the optical signals in the PIC 132, and the bonding layer 1343 may be electrically coupled to these active devices and/or passive devices. The bonding layers (1323 and 1343) may each include bonding pads (e.g., 132P, 134P) laterally covered by a bonding dielectric layer (e.g., 132D, 134D). The bonding pads 132P of the PIC 132 may be bonded to the bonding pads 134P of the EIC 134 in a one-to-one correspondence. The bonding dielectric layer 132D of the PIC 132 may be fused to the bonding dielectric layer 134D of the EIC 134.

With continued reference to FIG. 1C, the lateral dimension of the PIC 132 may be greater than that of the EIC 134. A dielectric layer 136 may be formed on the PIC 132 and extend along the first sidewall 134W of the EIC 134. In some embodiments, the dielectric layer 136 further covers the backside 1341b of the EIC 134. The material of the dielectric layer 136 is not particularly limited, and may be selected on the basis of its refractive index. The dielectric layer 136 may be transparent to light radiation in the target wavelength range. For example, the dielectric layer 136 includes an inorganic material, such as an oxide (e.g., silicon oxide), a nitride, carbide, or the like. The dielectric layer 136 may include a first side 136a connected to the bonding dielectric layer 132D of the PIC 132, a second side 136b opposite to the first side 136a, and an outer sidewall 136W connected to the first side 136a and the second side 136b. In some embodiments, the dielectric layer 136 is referred to as a gap-fill oxide.

Still referring to FIG. 1C, the IC die 130 may include an optical element 131 stacked over the EIC 134 and the dielectric layer 136. For example, the optical element 131 includes a first side 131a bonded to the dielectric layer 136, a second side 131b opposite to the first side 131a, an optical interface 131L formed at the second side 131b and optically aligned with (or optically coupled to) the optical component(s) 1326 of the PIC 132, and opposing outer sidewalls (131W and 131X) respectively connected to the first side 131a and the second side 131b. In some embodiments, the optical element 131 includes a substrate 1311 and a bonding dielectric layer 1312 formed at the first side 131a of the optical element 131 and bonding the substrate 1311 to the second side 136b of the dielectric layer 136. For example, the bonding dielectric layer 1312 and the dielectric layer 136 are bonded together through fusion bonding. The optical interface 131L may be recessed from the topmost surface 1311t of the substrate 1311. In some embodiments, the optical interface 131L is a convex surface acting as a lens. For example, the topmost point 131LT of the optical interface 131L is between the topmost point of the second side 131b and the first side 131a. The vertical distance VD1 measured between the topmost point 131LT of the optical interface 131L and the virtual plane VP1 on which the topmost point of the second side 131b of the substrate 131 is located may be non-zero. In some embodiments, the maximum thickness 131H of the optical element 131 is greater than the maximum thickness 13H of the combination of the dielectric layer 136, the EIC 134, and the PIC 132. For example, a ratio of the maximum thickness 131H to the maximum thickness 13H is in a range of about 24 and about 40. The maximum thickness 131H of the optical element 131 may be in a range of about 720 microns and about 800 microns. The maximum thickness 13H of the combination of the dielectric layer 136, the EIC 134, and the PIC 132 may be in a range of about 20 microns and about 30 microns. It is realized that the thickness ranges are examples and may be changed to other suitable values depending on product requirements.

Still referring to FIG. 1C, in some embodiments, the IC die 130 includes a protective film 133 formed on the second side 131b of the optical element 131 and covering the optical interface 131L for protection. For example, the protective film 133 has a planar top surface 133t. The protective film 133 may be transparent to light radiation in the target wavelength range. For example, during the operation, the incident light passes through the protective film 133, through the optical interface 131L of the optical element 131, through the dielectric layer 136, and toward the optical component(s) 1326 of the PIC 132. The protective film 133, the optical interface 131L, and the dielectric layer 136 may be considered as a part of the optical path of the IC die 130. The material of the protective film 133 is not particularly limited, and may be selected on the basis of its refractive index. For example, the protective film 133 includes an inorganic material, such as an oxide (e.g., silicon oxide), a nitride, carbide, or the like. The refractive index and the thickness of the protective film 133 may be adjusted according to the refractive indices of the optical interface 131L in order to meet the optical requirements of the IC die 130. The maximum thickness 133H of the protective film 133 may be less than the maximum thickness 13H and the maximum thickness 131H. For example, a ratio of the maximum thickness 13H to the maximum thickness 133H is in a range of about 2 and about 6. In some embodiments, the maximum thickness 133H of the protective film 133 is in a range of about 5 microns and about 10 microns. It is realized that the thickness range is an example and may be changed to other suitable values depending on product requirements.

With continued reference to FIG. 1C, the protective film 133 may be replaced with the protective film 133′. The protective film 133′ may be similar to the protective film 133, except that the protective film 133′ conformally lines the second side 131b of the optical element 131 and the optical interface 131L. For example, the protective film 133′ has a curved top surface 133t′ conformally lining the optical interface 131L. In alternative embodiments, the protective film (133 or 133′) is omitted.

Still referring to FIG. 1C, the sacrificial film 31 may be formed on the protective film 133 (or 133′) according to some embodiments. Alternatively, the sacrificial film 31 is directly formed on the second side 131b of the optical element 131 and the optical interface 131L without any protective film interposed therebetween. During the formation of the IC die 130, the sacrificial film 31 may be attached to the backside of the IC die 130 and then singulated along with the IC die 130. The first sidewall 31W of the sacrificial film 31 may be substantially leveled (or coplanar) with the outer sidewall 131W of the optical element 131, the outer sidewall 136W of the dielectric layer 136, and the first sidewall 132W of the PIC 132, within process variations. The second sidewall 31X of the sacrificial film 31 may be substantially leveled (or coplanar) with the outer sidewall 131X of the optical element 131, the second sidewall 134X of the EIC 134 and the second sidewall 132X of the PIC 132, within process variations.

Referring to FIG. 1D and with reference to FIG. 1C, the optical interface 131L may be encircled by a recess 131R. In the cross-sectional view of FIG. 1C, the optical interface 131L may be the convex top surface which is rounded or curved outwardly from the bottom surface 131RB of the recess 131R. The protective film 133 may extend into the recess 131R to surround the optical interface 131L. In the top view of FIG. 1D, the optical interface 131L may have a circular top-view shape, and the recess 131R may be formed as a close loop surrounding the perimeter of the optical interface 131L. Alternatively, the optical interface 131L and/or the recess 131R may have different top-view shapes than shown. In some embodiments, a plurality of optical interfaces (e.g., lens) 131L is arranged in an array over the PIC 132. In some embodiments, the number of the optical interfaces (e.g., lens) 131L is in a range of about 20 to about 24. It is noted that the size, the number, and the configuration of the PIC 132 and/or the EIC 134 and/or the optical element 131 are depicted for illustration purpose only. It is also noted that the protective film 133 and the sacrificial film 31 are omitted in the FIG. 1D to more clearly illustrate details of the optical element 131.

Referring back to FIG. 1C, the IC die 130 may include die connectors 137 formed below the contact pads 1325 of the PIC 132 and electrically connected to the TSVs 1322. The side of the IC die 130 where the die connectors 137 are distributed on may be viewed as an active side of the IC die 130. The die connectors 137 may be formed of a conductive material that is reflowable (e.g., solder), or include one or more suitable conductive material(s) such as copper, aluminum, gold, nickel, silver, palladium, tin, the like, or a combination thereof. A CP testing may be performed on the IC die 130 to ascertain whether the IC die 130 is a KGD. Thus, only IC dies 130, which are KGDs, undergo subsequent processing and are packaged, while other dies, which fail the CP testing, are not packaged. It should be noted that the configuration of the IC die 130 may be different than shown.

FIGS. 2A-2B and FIGS. 2E-2I are schematic cross-sectional views illustrating a manufacturing method of a semiconductor package at various stages, and FIGS. 2C-2D are schematic top views illustrating different configurations of the structure shown in FIG. 2B, in accordance with some embodiments. Although method embodiments are discussed as being performed in a particular order, other embodiments may be performed in any logical order.

Referring to FIG. 2A and with reference to FIGS. 1A-1C, one or more IC dies (e.g., 110, 120, and 130) may be disposed on and electrically coupled to an interposer 140′, where the IC dies may include similar devices and/or different devices. For example, the embodiments shown herein include the IC die 110, the IC die 120, and the IC die 130, in which the IC die 130 including the optical interface 131L may have different functions than the IC dies 110 and 120. At this stage, the IC die 130 may remain covered by the sacrificial film 31. The IC dies 110 and 120 may each have a single function (e.g., a logic device, a memory die, etc.), or may have multiple functions (e.g., a system-on-chip or the like). In an embodiment, the IC die 110 is a logic device (e.g., a CPU die or a SoC die) and the IC die 120 are a memory device (e.g., a HBM module). A lateral distance LD1 between adjacent two of the sidewalls (e.g., 110c and 120c, or 110c and 130c) of the IC dies (e.g., 110 and 120, or 110 and 130) may be non-zero. For example, the lateral distance LD1 is in a range of about 50 μm and about 100 μm. In some embodiments, a height 130H of the IC die 130 is less than a height 110H of the IC die 110. The height 130H of the IC die 130 may also be less than a height 120H of the IC die 120. It is realized that the distance range and the height are examples and may be changed to other suitable values depending on product requirements.

With continued reference to FIG. 2A, the interposer 140′ may include a substrate 142, through substrate vias (TSVs) 144, and an interconnect structure 146. The material of the substrate 142 may be selected from the candidate substrate materials of the semiconductor substrate 111 described in FIG. 1A. Devices (e.g., transistors, capacitors, resistors, diodes, and the like) may be formed in and/or on a front side 142a of the substrate 142. The TSVs 144 may be formed to extend from the front side 142a of the substrate 142 into the substrate 142. At this stage, the TSVs 144 may not reach the backside 142b of the substrate 142. The interconnect structure 146 may be formed over the front side 142a of the substrate 142, and may be used to form electrical connections between the devices of the substrate 142 (if any), the TSVs 144, and/or external devices. The interconnect structure 146 may include a dielectric layer 1461 and metallization pattern 1462 formed in the dielectric layer 1461. The metallization patterns 1462 may be redistribution layers (RDLs) that include metal vias, metal pads, and/or metal lines that form the electrical connections. In some embodiments, the interconnect structure 146 is referred to a redistribution structure or a fan-out redistribution structure. The interposer 140′ may include contact pads 1463 disposed on the interconnect structure 146 and coupled to the die connectors (e.g., 117, 127, and 137) of the IC dies (e.g., 110, 120, and 130). The IC dies (e.g., 110, 120, and 130) may be electrically connected to one another through the interconnect structure 146 and the contact pads 1463. In some embodiments, the IC die 130 has one or more IC die(s) 110 and/or 120 associated with it and which may be electrically connected to the IC die 130 (e.g., through the interconnect structure 146 and the contact pads 1463).

Referring to FIG. 2B and with reference to FIG. 2A, an underfill layer 151 may be formed on the interposer 140′ to at least surround the electrical connections between the IC dies (e.g., 110, 120, and 130) and the interposer 140′ such as the contact pads 1463 and the die connectors (e.g., 117, 127, and 137). The underfill layer 151 may be any acceptable material, such as a polymer, epoxy, or the like, and may be formed by a capillary flow process or other suitable dispensing techniques. In some embodiments, the underfill layer 151 is omitted. An encapsulant material 152′ may be formed on the interposer 140′ to embed the IC dies (e.g., 110, 120, and 130) and the underfill layer 151 (if present) therein. For example, the encapsulant material 152′ is formed over the interconnect structure 146, and the IC dies (e.g., 110, 120, and 130) and the underfill layer 151 (if present) are surrounded and covered by the encapsulant material 152′. In some embodiments, the sacrificial film 31 on the IC die 130 may be embedded in the encapsulant material 152′ at this stage.

With continued reference to FIG. 2B, the encapsulant material 152′ may be or include a molding compound, epoxy, or the like, and may be applied by compression molding, transfer molding, or the like. The encapsulant material 152′ may include a base material 152M (e.g., a polymer, an epoxy, etc.), and fillers 152F in the base material 152M. The fillers 152F may include dielectric particles of silicon oxide, aluminum oxide, silica, or the like, and may have spherical shapes. The spherical fillers 152F may have the same diameter or different diameters. In some embodiments, the encapsulant material 152′ is applied in liquid or semi-liquid form and then subsequently cured. In an embodiment where the underfill layer 151 is omitted, the encapsulant material 152′ is a molding underfill which extends into a gap between the respective IC die (e.g., 110, 120, and 130) and the interposer 140′ to surround the contact pads 1463 and the die connectors (e.g., 117, 127, and 137).

Referring to FIG. 2C and with reference to FIG. 2B, FIG. 2B may be a cross-sectional view of the structure taken along the line 2B-2B of FIG. 2C. In the top view, the IC die 110 may be disposed in the central region, while the IC dies (120 and 130) may be disposed in the peripheral region and lateral aside the IC die 110. Although a single IC die 110 is illustrated, the number of the IC die 110 may be two or more depending on product requirements. For example, a plurality of IC dies 120 is arranged in a row along one side of the IC die 110, and a plurality of IC dies 130 is arranged in a row along an opposing side of the IC die 110. In some embodiments, the IC dies 120 and 130 are arranged in a row along a side of the IC die 110. In some embodiments, one or more die(s) 90 are arranged at the blank area in the encapsulant material 152′. The dies 90 may have the same size or may include different sizes depending on product requirements. In some embodiments, the dies 90 include dummy dies, and the inclusion of the dummy dies may improve warpage characteristics of the resulting package. The resulting package may experience less warpage and/or more symmetrical warpage when one or more dummy dies are included therein. In some embodiments, the dies 90 include input/output dies electrically coupled to the interposer 140′ depending on circuit and product requirements.

Referring to FIG. 2D and with reference to FIG. 2C, the configuration of FIG. 2D may be similar to the configuration of FIG. 2C, except that the IC dies (120 and 130) are arranged at all (e.g., four) sides of the IC die 110 in the top view. Although a single IC die 110 is illustrated, the number of the IC die 110 may be two or more depending on product requirements. For example, the IC dies 120 are arranged in rows at two opposing sides of the IC die 110, while the IC dies 130 are arranged in rows at the other two opposing sides of the IC die 110. One or more die(s) 90 may be arranged at the corner between the IC dies (120 and 130) and may be covered by the encapsulant material 152′. It should be appreciated that these configurations are examples, and other configurations or arrangements are possible.

Referring to FIG. 2E and with reference to FIG. 2B, a thinning process (e.g., chemical-mechanical polishing (CMP), grinding, etching, a combination thereof, etc.) may be performed on the backside 142b of the substrate 142 of the interposer 140′ until at least a portion of the TSVs 144 is accessibly exposed so as to form an interposer 140. In some embodiments, thinned surfaces 142b′ of the substrate 142 and exposed surfaces 144b of the TSVs 144 are substantially leveled (or coplanar), within process variations. In some embodiments, the interposer 140 includes contact pads 147 formed on the thinned surfaces 142b′ of the substrate 142 and electrically connected to the exposed surfaces 144b of the TSVs 144. In some embodiments, conductive bumps 148 are formed on the contact pads 147. The conductive bumps 148 may be formed of a conductive material that is reflowable (e.g., solder), or may include other suitable conductive material(s) such as copper, aluminum, gold, nickel, silver, palladium, tin, the like, or a combination thereof. The conductive bumps 148 may be solder balls, metal pillars, controlled collapse chip connection (C4) bumps, micro-bumps, electroless nickel-electroless palladium-immersion gold technique (ENEPIG) formed bumps, or the like. During the thinning process and the formation of the contact pads 147 and the conductive bumps 148, the encapsulant material 152′ may function as a structural support, and the sacrificial film 31 may remain embedded in the encapsulant material 152′ at this stage.

Referring to FIG. 2F and with reference to FIG. 2E, the conductive bumps 148 may be attached to a supporting tape 41. For example, the conductive bumps 148 (and the contact pads 147, if desired) are embedded in the supporting tape 41. The supporting tape 41 may be provided in a wafer form for performing the wafer-level package processes. In some embodiments, a thinning process (e.g., CMP, grinding, etching, a combination thereof, etc.) is performed on the encapsulant material 152′ to form an encapsulant 152. As shown in the enlarged view, a portion of the fillers 152F at the top surface 152b of the encapsulant 152 may be planarized and may be accessibly exposed by the base material 152M. The planarized fillers 152F′ may render the top surface 152b uneven. During the thinning of the encapsulant material 152′, the supporting tape 41 may functions as a support. In some embodiments, after thinning of the encapsulant material 152′, the sacrificial film 31 is accessibly exposed by the encapsulant 152 for further processing. The backsides (e.g., 110b and 120b) of the IC dies (e.g., 110 and 120) may also be accessibly exposed by the encapsulant 152. The thinning process may planarize the structure such that the top surface 152b of the encapsulant 152 is substantially leveled (or coplanar) with the backsides (e.g., 110b and 120b) of the IC dies (e.g., 110 and 120), within process variations.

Referring to FIG. 2G and with reference to FIG. 2F, the sacrificial film 31 may be removed to expose the IC die 130. For example, the protective film 133 of the IC die 130 is accessibly exposed after removing the sacrificial film 31. The removal of the sacrificial film 31 may include applying suitable light illumination (e.g., ultra-violet (UV) light, laser irradiation, etc.) to the sacrificial film 31, and then using suitable water/solvent to dissolve the sacrificial film 31. The exposure to light may cause a chemical change that allows the sacrificial film 31 soluble in suitable solvent. The sacrificial film 31 may be soluble by flushing, rinsing, or soaking using water or solvent, depending on the material properties of the sacrificial film 31. In some embodiments, instead of applying light illumination, the sacrificial film 31 is removed by applying a solution (e.g., an alkaline solution or the like). For example, the sacrificial film 31 is soluble in deionized water, isopropanol, acetone, alkaline solution, and/or the like. In some embodiments, hot water is used to remove the sacrificial film 31, where the desired temperature of the hot water is from about 25° C. to about 60° C. It should be appreciated that the removal method of the sacrificial film 31 is dependent upon the properties of the selected material of the sacrificial film 31 and construed no limitation in the disclosure.

With continued reference to FIG. 2G, after removing the sacrificial film 31, the inner sidewall 152c of the encapsulant 152 connected to the top surface 152b may be accessibly exposed. A surface roughness of the top surface 152b of the encapsulant 152 may be greater than a surface roughness of the inner sidewall 152c of the encapsulant 152. The surface roughness of the inner sidewall 152c of the encapsulant 152 may be greater than the surface roughness of the outermost surface 133b of the protective film 133. In some embodiments, the inner sidewall 152c of the encapsulant 152 is substantially vertical (or slightly slanted depending on the profile of the sacrificial film). The outermost surface 133b of the protective film 133 may be lower than the top surface 152b of the encapsulant 152, and the vertical distance between the outermost surface 133b of the protective film 133 may be substantially equal to the height of the inner sidewall 152c of the encapsulant 152.

Referring to FIG. 2H and with reference to FIG. 2G, the structure illustrated in FIG. 2G may be flipped over and attached to a tape frame 43 for further processing. Since the sacrificial film 31 on the IC die 130 has already been removed, the outermost surface 133b of the protective film 133 may be in contact with the tape frame 43. The supporting tape 41 may be removed from the interposer 140 to accessibly expose the conductive bumps 148 and the contact pads 147. In some embodiments where the aforementioned processes are performed in wafer level, a singulation process S43 is performed to dice the interposer 140 and the encapsulant 152 so as to form a plurality of device packages 100. The tape frame 43 may serve as a support during the singulation process S43, and may thus be referred to as a dicing frame.

Referring to FIG. 2I and with reference to FIG. 2H, one or more device package(s) 100 may be attached to a package substrate 220 to form a semiconductor package 10. The semiconductor package 10 may be viewed as a three-dimensional integrated circuit (3DIC) package. In some embodiments, the semiconductor package 10 is referred to as a chip-on-wafer-on-substrate (CoWoS) package. The package substrate 220 may be electrically connected to the IC dies (e.g., 110, 120, and 130) through the interposer 140. For example, the package substrate 220 includes a substrate core 222, which may be made of one or more semiconductor material(s), one or more compound material(s), the like, or combinations thereof. Alternatively, the substrate core 222 is an insulating core (e.g., FR4, bismaleimide-triazine (BT) resin, etc.). In alternative embodiments, the substrate core 222 is made of one or more printed circuit board material(s), and build up films (e.g., Ajinomoto build-up film (ABF) or other laminates) may be used for the substrate core 222. The substrate core 222 may include active and/or passive devices (not separately illustrated) to generate the functional requirements of the design for the system. The substrate core 222 may also include metallization layers and vias (not individually shown) to electrically connect the various devices to form functional circuitry.

With continued reference to FIG. 2I, the package substrate 220 may include bond pads 224 formed over the substrate core 222. The conductive bumps 148 may be reflowed to attach the contact pads 147 to the bond pads 224. In some embodiments, an underfill layer 228 is formed between the device package 100 and the package substrate 220 to surround the conductive bumps 148, the contact pads 147, and the bond pads 224. The underfill layer 228 may be formed by a capillary flow process after the device package 100 is attached or may be formed by any suitable deposition method before the device package 100 is attached. The underfill layer 228 may be a continuous material extending from the package substrate 220 to the sidewall of the interposer 140. In some embodiments, external terminals 226 are formed below the substrate core 222. The external terminals 226 may be ball grid array (BGA) connectors, solder balls, metal pillars, C4 bumps, micro-bumps, ENEPIG formed bumps, or the like.

Still referring to FIG. 2I, the IC die 130 (e.g., the OE die) may be included in the device package 100 and electrically coupled to other IC dies (e.g., 110 and/or 120) through the interconnect structure 146 of the interposer 140. The interconnect structure 146 may be formed having fine line/spacing for matching die connector density of the respective IC die (e.g., 110, 120, and 130) so as to improve electrical/signal performance and achieve higher data transmission rate. Since the IC die 130 (e.g., the OE die) is integrated into the device package 100 instead of using the routing layer in the package substrate 220, the signal bandwidth of the semiconductor package 10 may be no longer constrained by the limitation of substrate processing. The optical interface 131L of the IC die 130 may be protected from being ground using the protective film 133 and the sacrificial film 31 overlying the protective film 133 when performing the thinning process on the encapsulant material 152′ (see FIG. 2F), and then the sacrificial film 31 may be removed to expose the protective film 133 after the thinning process. In this manner, damage to the optical interface 131L of the IC die 130 may be prevented, and the sidewalls of the IC die 130 may remain protected by the encapsulant 150, thereby improving the reliability of the device package 100.

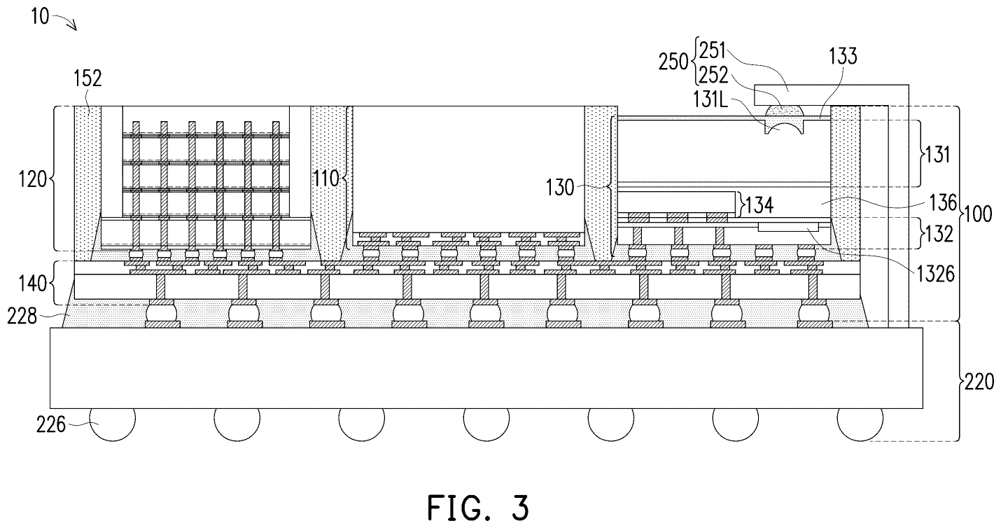

FIG. 3 is a schematic cross-sectional view illustrating the semiconductor package of FIG. 2I coupled to an optical signal port, in accordance with some embodiments. Referring to FIG. 3 and FIG. 2I, an optical signal port 250 may be coupled to the semiconductor package 10. For example, the optical signal port 250 is attached to the package substrate 220 and optically coupled to the optical interface 131L of the IC die 130. The optical signal port 250 may include at least one fiber 251 and an optical interface layer 252 interposed between the fiber 251 and the protective film 133 of the IC die 130 for bonding the fiber 251 to the device package 100. The fiber 251 may be optically aligned with the IC die 130 (e.g., the OE die) to enable exchange of optical signals between the fiber 251 and the optical component(s) 1326 of the PIC 132 through the optical interface 131L. For example, the fiber 251 is bonded to the IC die 130 by applying the optical interface layer 252 to the fiber 251 and the protective film 133 of the IC die 130. The optical interface layer 252 may include clear (or transparent) adhesive or other suitable optical glue/grease. In some embodiments, the optical interface layer 252 is a layer of index-matching adhesive and may be index-matched to the fiber 251 and to the protective film 133 and the optical interface 131L of the IC die 130 to reduce optical loss. The refractive index and the thickness of the optical interface layer 252 may be adjusted according to the refractive indices of the fiber 251, the protective film 133, and the optical interface 131L. It should be noted that the optical signal port 250 may have a different configuration than shown.

FIGS. 4A-4D are schematic cross-sectional views illustrating a manufacturing method of a semiconductor package at various stages, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2I.

Referring to FIG. 4A and with reference to FIG. 2B, the structure shown in FIG. 4A may be similar to the structure shown in FIG. 2B, except that the sacrificial film 31 is omitted in FIG. 4A. For example, the IC die 130 (shown in FIG. 1C) is not provided with the sacrificial film 31, and after attaching the IC die 130 to the interposer 140 (see FIG. 2A), the backside of the IC die 130 may be exposed and face upwardly. After forming the encapsulant material 152′, the outermost surface 133b of the protective film 133 of the IC die 130 may be covered by the encapsulant material 152′.

Referring to FIG. 4B and with reference to FIG. 4A and FIGS. 2E-2F, the thinning process may be performed on the substrate 142 of the interposer 140′ until at least a portion of the TSVs 144 is accessibly exposed so as to form the interposer 140 (see FIG. 2E). The contact pads 147 and the conductive bumps 148 may be sequentially formed on the thinned surfaces 142b′ of the substrate 142 to be electrically coupled to the TSVs 144 (see FIG. 2E). The conductive bumps 148 may then be attached to the supporting tape 41 for further processing (see FIG. 2F). The thinning process may be performed on the encapsulant material 152′ (see FIG. 2F) to form an encapsulant 152″. After the thinning, the backsides (e.g., 110b and 120b) of the IC dies (e.g., 110 and 120) may be accessibly exposed by the encapsulant 152″. The top surface 152b of the encapsulant 152″ may be substantially leveled (or coplanar) with the backsides (e.g., 110b and 120b) of the IC dies (e.g., 110 and 120), within process variations. At this stage, the IC die 130 may not be revealed by the encapsulant 152″. For example, the backside 1341b of the EIC 134 and the second side 136b of the dielectric layer 136 remain covered by the encapsulant 152″ at this stage.

Referring to FIG. 4C and with reference to FIG. 4B, a removing process S45 may be performed on the encapsulant 152″ to form an encapsulant 152-1 having an opening 152P (or a hollow region), where at least a portion of the protective film 133 directly over the optical interface 131L is accessibly exposed by the opening 152P. For example, the opening 152P is formed using a suitable process such as a laser drilling process, an etching process, a combination thereof, or the like. In some embodiments, the etching process is a plasma etching (or plasma bombardment) process. For example, laser energy is applied onto the encapsulant 152″ to form the opening 152P. After the laser drilling process, the residues of the encapsulant 152″ may be left on the IC die 130. In some embodiments, the residues of the encapsulant 152″ are removed through a plasma cleaning process, in which the plasma of process gases may be used to bombard the residue of the encapsulant 152″. Alternatively, the residues of the encapsulant 152″ are removed through any suitable etching/cleaning process.

With continued reference to FIG. 4C, after the removing process S45, an inner sidewall 152c′ of the encapsulant 152-1 connected to the top surface 152b may be accessibly exposed. In some embodiments, during the removing process S45, a portion of the base material 152M and a portion of the fillers 152F corresponding to the location of the opening 152P are removed. For example, partially removed fillers 152F″ are accessibly revealed by the base material 152M as shown in the enlarged view. The partially removed fillers 152F″ may render the inner sidewall 152c′ uneven. A surface roughness of the inner sidewall 152c′ of the encapsulant 152-1 may be greater than the surface roughness of the top surface 152b of the encapsulant 152-1. The surface roughness of the top surface 152b of the encapsulant 152-1 may be greater than that of the backside 1341b of the EIC 134.

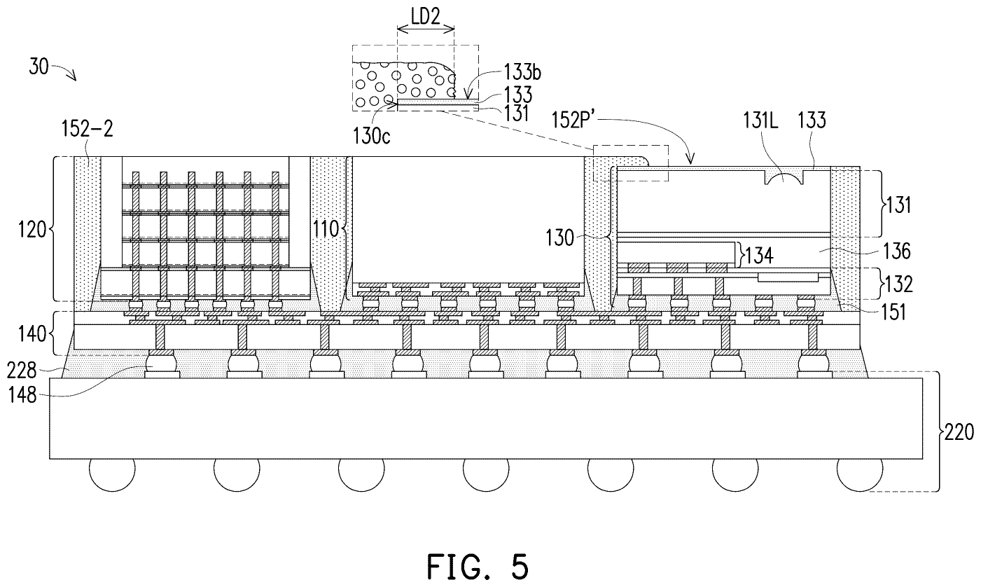

Still referring to FIG. 4C, the removing process S45 may leave the encapsulant 152-1 with upper inner sidewall c1 that is angled. In some embodiments, the upper inner sidewall c1 includes a rounded corner connected to the lower inner sidewall c2 and the top surface 152b. In some embodiments, at least a portion of the upper inner sidewall c1 is in a curved shape. For example, a concave-down surface profile is seen from the cross-sectional view as shown in FIG. 4C. In some embodiments, the upper inner sidewall c1 having the concave-down surface profile is viewed as a curved portion 152CP. For example, the inner sidewall 152c′ of the encapsulant 152-1 is substantially aligned with the sidewall 130c of the IC die 130. In some embodiments, a portion of the encapsulant 152″ opposite to the curved portion 152CP is removed to render the top surface 152b′ of the encapsulant 152-1 lower than the top surface 152b, as shown in the dashed box A. For example, the top surface 152b′ of the encapsulant 152-1 is substantially leveled with the outermost surface 133b of the protective film 133, as shown in the dashed box A. In some embodiments, the opposing sides of the opening 152P defined by the encapsulant 152-1 are arranged in a substantially symmetrical manner, as shown in the dashed box B. The opening 152P may have a different size than shown which will be discussed in accompanying with FIG. 5.

Referring to FIG. 4D and with reference to FIG. 4C and FIGS. 2H-2I, the supporting tape 41 may be removed from the interposer 140, and a singulation process may be performed to dice the interposer 140 and the encapsulant 152-1 so as to form a plurality of device packages 100-1. The steps may be similar to the processes described in FIG. 2H, and thus the detailed description are not repeated for simplicity. One or more device package(s) 100-1 may be attached to the package substrate 220 using the conductive bumps 148. The underfill layer 228 is optionally formed between the device package 100-1 and the package substrate 220 to protect the electrical connections therebetween. The steps may be similar to the processes described in FIG. 2I, and thus the detailed descriptions are not repeated for simplicity.

With continued reference to FIG. 4D and FIG. 2I, a semiconductor package 20 may be provided. The difference between the semiconductor package 20 shown in FIG. 4D and the semiconductor package 10 shown in FIG. 2I includes that the encapsulant material may be in direct contact with the protective film 133 of the IC die 130, and then the protective film 133 of the IC die 130 is revealed by forming the opening 152P in the encapsulant material. The optical interface 131L of the IC die 130 may be protected from being ground by the protective film 133, and the thinning of the encapsulant material is performed prior to the formation of the opening 152P of the encapsulant 152-1.

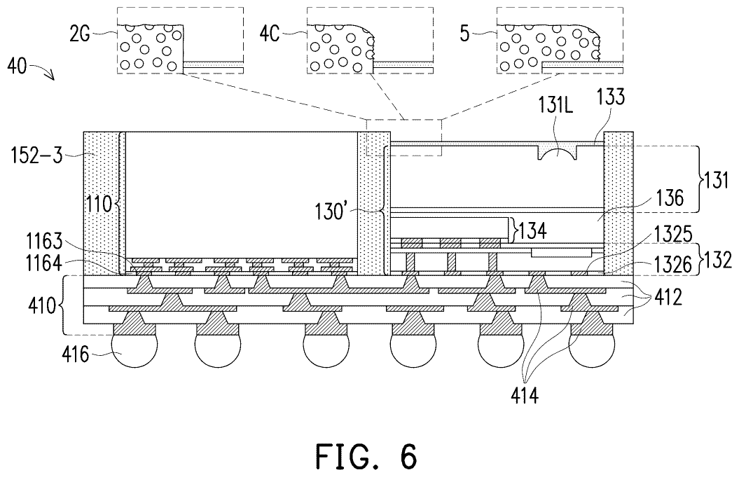

FIGS. 5-6 are schematic cross-sectional views illustrating a semiconductor package, in accordance with alternative embodiments. Unless explicitly stated otherwise, the materials and the formation methods of the components in these embodiments are essentially the same as the like components, which are denoted by like reference numerals in the embodiments described in accompanying with FIG. 2I and FIG. 4D.

Referring to FIG. 5 and with reference to FIG. 4D, a semiconductor package 30 may be similar to the semiconductor package 20 shown in FIG. 4D, except that the encapsulant 152-2 of the device package 100-2 extends to cover at least a portion of the backside of the IC die 130. The portion of the outermost surface 133b of the protective film 133 directly over the optical interface 131L may remain unmasked by the encapsulant 152-2. In the illustrated embodiment, the encapsulant 152-2 covers the sidewall 130c of the IC die 130 and extends to cover a portion of the outermost surface 133b of the protective film 133. For example, a lateral dimension LD2 of a portion of the encapsulant 152-2 directly on the outermost surface 133b of the protective film 133 is non-zero. In some embodiments, the lateral dimension LD2 is in a range of about 2 μm and about 5 μm. It is realized that the ranges of the lateral dimension LD2 is an example and may be changed to other suitable values depending on product requirements.

Referring to FIG. 6 and with reference to FIG. 2I or FIG. 4D, a semiconductor package 40 may be provided. In some embodiments, the semiconductor package 40 is an integrated fan-out (InFO) package. For example, the semiconductor package 40 includes an IC die 110′ and an IC die 130′ disposed side-by-side and laterally covered by the encapsulant 152-3. The IC die 110′ may be similar to the IC die 110 described in FIG. 1A, except that the contact pads 1163 of the IC die 110′ may serve as the die connectors for further electrical connection. In the illustrated embodiment, the contact pads 1163 are laterally covered by a passivation layer 1164. Alternatively, the passivation layer 1164 is omitted, and the contact pads 1163 may be laterally covered by the encapsulant 152-3. The IC die 130′ may be similar to the IC die 130 described in FIG. 1C, except that the contact pads 1325 of the IC die 130′ may serve as the die connectors for further electrical connection. In the illustrated embodiment, the contact pads 1325 are laterally covered by a passivation layer 1326. Alternatively, the passivation layer 1326 is omitted, and the contact pads 1325 may be laterally covered by the encapsulant 152-3. Although two IC dies (110′ and 130′) are illustrated herein, more than two IC dies with the same type or different types (e.g., the IC die 120) may be packaged by using the encapsulant 152-3.

With continued reference to FIG. 6, a redistribution structure 410 may be formed on the encapsulant 152-3 and the IC dies (110′ and 130′). In some embodiments, the redistribution structure 410 is referred to as a fan-out redistribution structure or an interconnect structure. The redistribution structure 410 may provide electrical interconnections between the IC dies (110′ and 130′). The redistribution structure 410 may include dielectric layers 412 and metallization patterns 414. The metallization patterns 414 may include metal lines, metal vias, metal pads, etc. In some embodiments, the metal vias of the metallization patterns 414 are in physical and electrical contact with the contact pads 1325 of the IC die 130′ and the contact pads 1163 of the IC die 110′. The metallization patterns 414 may re-route the signal between the IC dies (110′ and 130′) and may be referred to as redistribution layers (RDLs). The redistribution structure 410 is shown as an example having three layers of metallization patterns 414 and three dielectric layers 412. More or fewer dielectric layers 412 and metallization patterns 414 may be formed in the redistribution structure 410. The semiconductor package 40 may include external terminals 416 formed below the redistribution structure 410. The external terminals 416 may be BGA connectors, solder balls, metal pillars, C4 bumps, micro-bumps, ENEPIG formed bumps, or the like.

With continued reference to FIG. 6, the backside of the IC die 130′ may be partially or fully exposed by the encapsulant 152-3 as shown in the dashed boxes (2G, 4C, and 5), where the dashed box 2G corresponds to the enlarged view shown in FIG. 2G, the dashed box 4C corresponds to the enlarged view shown in FIG. 4C, and the dashed box 5 corresponds to the enlarged view shown in FIG. 5. The details of the relationship between the encapsulant 152-3 and the IC die 130′ may be found in the embodiments shown in FIGS. 2G, 4C, and 5, and are not repeated herein.

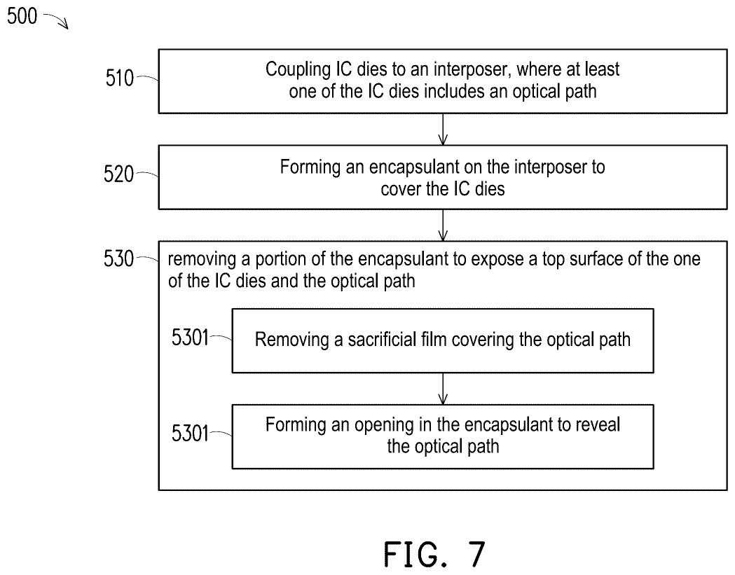

FIG. 7 is a flowchart illustrating a method 500 of forming a semiconductor package, in accordance with some embodiments. Although this method and other methods illustrated and/or described herein are illustrated as a series of acts or events, it will be appreciated that the disclosure is not limited to the illustrated ordering or acts. The acts may be carried out in different orders than illustrated, and/or may be carried out concurrently. The illustrated acts or events may be subdivided into multiple acts or events, which may be carried out at separate times or concurrently with other acts or sub-acts. Some illustrated acts or events may be omitted, and other un-illustrated acts or events may be included. Acts may correspond to the structure previously illustrated in FIGS. 2A-2B and 2E-2I or FIGS. 4A-4D.

At the act 510, IC dies may be coupled to an interposer (or an interconnect structure/a redistribution structure), where at least one of the IC dies (e.g., the IC die 130) includes an optical path (e.g., including the optical interface 131L and portions of the protective film 133 and the dielectric layer 136 which are optically coupled to the optical interface 131L). FIG. 2A illustrates a cross-sectional view of some embodiments corresponding to the act 510.

At the act 520, an encapsulant may be formed on the interposer to cover the IC dies. FIGS. 2B and 2E-2F and FIGS. 4A-4B illustrate cross-sectional views of some embodiments corresponding to the act 520.

At the act 530, a portion of the encapsulant is removed to expose a top surface of the one of the IC dies (e.g., the IC die 130) and the optical path. In some embodiments, since the top surface of the IC die 130 is fully or partially exposed by the encapsulant, the heat dissipation of the IC die 130 is improved. The optical path of the IC die 130 may be revealed by the encapsulant to facilitate the optical signal transmission. FIG. 2G and FIG. 4C illustrate cross-sectional views of some embodiments corresponding to the act 530. At the sub-act 5301, a sacrificial film covering the optical path may be removed. FIG. 2G illustrates a cross-sectional view of some embodiments corresponding to the act 5301. At the sub-act 5302, an opening is formed in the encapsulant to reveal the optical path. FIG. 4C illustrates a cross-sectional view of some embodiments corresponding to the act 5302. Note that multiple subsequent steps (e.g., forming metallization layers and other back end of line (BEOL) steps/packaging steps) may be performed to produce a usable working semiconductor package.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor package includes a first die and a second die disposed side-by-side, an encapsulant laterally covering the first die and the second die, and an interconnect structure underlying the encapsulant. Each of the first die and the second die includes a front side and a back side opposite to each other. The second die further includes an optical interface at the back side, and a top surface of the back side of the second die and the optical interface are exposed by the encapsulant. The interconnect structure is connected to the front sides of the first and second dies, and the second die is electrically coupled to the first die through the interconnect structure.

According to some embodiments, a semiconductor package includes a first die, a second die disposed laterally aside the first die, an interconnect structure, and an encapsulant disposed on the interconnect structure. The first die includes a front side, a back side opposite to the front side, and a sidewall connected to the front and the back side. The second die includes a PIC, an EIC disposed on and bonded to the PIC, a dielectric layer disposed on the PIC and covering the EIC, and an optical element disposed on the electronic integrated circuit and the dielectric layer, wherein the optical element includes an optical interface at a side opposite to the dielectric layer. The interconnect structure is connected to the front side of the first die and the PIC of the second die, and the second die is electrically coupled to the first die through the interconnect structure. The encapsulant is disposed on the interconnect structure and extending along the sidewall of the first die and a sidewall of the second die. The encapsulant includes an opening exposing the optical interface and an upper inner sidewall surrounding the opening. A height of the second die is less than that of the first die.

According to some embodiments, a manufacturing method of a semiconductor package includes: coupling a first die and a second die to an interposer, wherein the second die comprises an optical path; forming an encapsulant on the interposer to cover the first and second dies; and removing a portion of the encapsulant to expose a top surface of the second die and the optical path.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first die and a second die disposed side-by-side, each of the first die and the second die comprising a front side and a back side opposite to each other, the second die further comprising an optical interface at the back side;
an encapsulant laterally covering the first die and the second die, a top surface of the back side of the second die and the optical interface being exposed by the encapsulant; and
an interconnect structure underlying the encapsulant and connected to the front sides of the first and second dies, the second die being electrically coupled to the first die through the interconnect structure.

2. The semiconductor package of claim 1, wherein the back side of the second die is between a top surface of the encapsulant and the front side of the second die.

3. The semiconductor package of claim 1, wherein a topmost point of the optical interface of the second die is between the back side of the second die and the front side of the second die.

4. The semiconductor package of claim 1, wherein the second die comprises a photonic integrated circuit, an electronic integrated circuit disposed on and bonded to the photonic integrated circuit, and a dielectric layer disposed on the photonic integrated circuit and covering a sidewall and a top surface of the electronic integrated circuit.

5. The semiconductor package of claim 4, wherein the second die further comprises an optical element comprising a first side bonded to the dielectric layer, a second side opposite to the first side, the optical interface disposed at the second side, and a recess disposed at the second side and encircling the optical interface.

6. The semiconductor package of claim 5, wherein the second die further comprises a protective film disposed on the second side of the optical element and filling the recess to cover the optical interface.

7. The semiconductor package of claim 1, wherein the encapsulant comprises a top surface and an inner sidewall connected to the top surface and intersected with the second die, and a surface roughness of the top surface of the encapsulant is greater than that of the inner sidewall of the encapsulant.

8. The semiconductor package of claim 7, wherein the inner sidewall of the encapsulant is substantially coplanar with a sidewall of the second die which is connected to the front side and the back side.

9. The semiconductor package of claim 1, wherein the encapsulant comprises a top surface and an inner sidewall connected to the top surface and intersected with the second die, and a surface roughness of the inner sidewall of the encapsulant is greater than that of the top surface of the encapsulant.

10. The semiconductor package of claim 1, wherein the encapsulant comprises a first top surface and a second top surface, the top surface of the back side of the second die is between the first and second top surfaces of the encapsulant, and the second top surface of the encapsulant is substantially coplanar with the top surface of the back side of the second die.

11. The semiconductor package of claim 1, wherein the interconnect structure is a part of an interposer or a redistribution structure.

12. A semiconductor package, comprising:
a first die comprising a front side, a back side opposite to the front side, and a sidewall connected to the front side and the back side;
a second die disposed laterally aside the first die, the second die comprising a photonic integrated circuit, an electronic integrated circuit disposed on and bonded to the photonic integrated circuit, a dielectric layer disposed on the photonic integrated circuit and covering the electronic integrated circuit, and an optical element disposed over the electronic integrated circuit and the dielectric layer, wherein the optical element comprises an optical interface at a side opposite to the dielectric layer, and a height of the second die is less than that of the first die;
an interconnect structure connected to the front side of the first die and the photonic integrated circuit of the second die, the second die being electrically coupled to the first die through the interconnect structure; and
an encapsulant disposed on the interconnect structure and extending along the sidewall of the first die and a sidewall of the second die, the encapsulant comprising an opening exposing the optical interface and an upper inner sidewall surrounding the opening.

13. The semiconductor package of claim 12, wherein a top surface of the encapsulant connected to the upper inner sidewall is higher than the optical interface of the second die, relative to the interconnect structure.

14. The semiconductor package of claim 13, wherein the upper inner sidewall of the encapsulant is angled and intersected with the second die.

15. The semiconductor package of claim 12, wherein the encapsulant laterally extends along sidewalls of the photonic integrated circuit, the electronic integrated circuit, the dielectric layer, and the optical element.

16. The semiconductor package of claim 12, wherein the encapsulant comprises a base material and fillers in the base material, a portion of the fillers is exposed by the base material at a top surface of the encapsulant.

17. The semiconductor package of claim 16, wherein another portion of the fillers is exposed by the base material at the upper inner sidewall of the encapsulant which is connected to the top surface of the encapsulant.

18. A manufacturing method of a semiconductor package, comprising:
coupling a first die and a second die to an interconnect structure, wherein the second die comprises an optical path;
forming an encapsulant on the interconnect structure to cover the first and second dies; and
removing a portion of the encapsulant to expose a top surface of the second die and the optical path.

19. The manufacturing method of claim 18, wherein the second die is provided with a sacrificial film covering the optical path, when forming the encapsulant, the optical path remains covered by the sacrificial film, and the manufacturing method further comprises:
removing the sacrificial film after removing the portion of the encapsulant.

20. The manufacturing method of claim 18, wherein removing the portion of the encapsulant comprises:
forming an opening in the encapsulant to at least expose the optical path of the second die.
